(19) United States
(12) Patent Application Publication
(10) Pub. No.: US 2024/0061332 A1
(43) Pub. Date: Feb. 22, 2024

(54) METHOD OF PATTERNING SEMICONDUCTOR LAYER

(71) Applicant: Raynergy Tek Incorporation, HSINCHU (TW)

(72) Inventors: Yi-Ming CHANG, HSINCHU (TW); Chia-Hua TSAI, HSINCHU (TW); Hsin-Yuan SU, HSINCHU (TW)

(21) Appl. No.: 18/055,416

(22) Filed: Nov. 15, 2022

(30) Foreign Application Priority Data
Aug. 4, 2022 (TW) 111129393

(51) Int. Cl. G03F 7/004

(52) U.S. Cl. CPC G03F 7/0048; G03F 7/162

(57) ABSTRACT

A method of patterning a semiconductor layer includes the following steps. The semiconductor layer is formed on a substrate. A photoresist layer is formed on the semiconductor layer. The photoresist layer is patterned to form an opening exposing an exposed region of the semiconductor layer. The exposed region of the semiconductor layer is dissolved with a solution to pattern the semiconductor layer, in which the solution includes a first organic solvent and a second organic solvent. The solubility of the semiconductor layer in the first organic solvent is greater than 1 mg/mL, and the solubility of the semiconductor layer in the second organic solvent is less than or equal to 1 mg/mL.

### CROSS-REFERENCE TO RELATED APPLICATION

This application claims priority to Taiwan Application Serial Number 111129393, filed Aug. 4, 2022, which is herein incorporated by reference.

### BACKGROUND

### Field of Invention

The present disclosure relates to a method of patterning semiconductor layer.

### Description of Related Art

Materials in semiconductor electronic components have gradually developed from silicon-based materials to organic semiconductor materials, such as non-crosslinked organic polymers, organic small molecules, fullerene derivatives, nanoparticles dispersed by coating with organic molecules, etc. Normally, a good semiconductor electronic component should not have a short circuit or a high resistance value from the remnants of the materials. Therefore, a problem to be solved is to pattern the above-mentioned new organic semiconductor materials to obtain the desired pattern.

Conventional patterning methods include wet etching and dry etching. However, the acidic or alkaline solutions used in wet etching cannot pattern the above-mentioned new organic semiconductor materials. Moreover, the acidic or alkaline solutions damage the organic semiconductor materials, thereby making the organic semiconductor materials lose their characteristics. Dry etching relies on the use of vacuum equipment and etching gases, which is not only costly and inconvenient but also complicates the process. Therefore, it is necessary to develop a novel method of patterning organic semiconductor materials to overcome the above-mentioned problems.

### SUMMARY

The present disclosure relates to a method of patterning semiconductor layer. The method includes the following operations. A semiconductor layer is formed on a substrate. A photoresist layer is formed on the semiconductor layer. The photoresist layer is patterned to form an opening that exposes an exposed region of the semiconductor layer in the photoresist layer. The exposed region of the semiconductor layer is dissolved with a solution to pattern the semiconductor layer, in which the solution includes a first organic solvent and a second organic solvent, a solubility of the semiconductor layer in the first organic solvent is greater than 1 mg/mL, and a solubility of the semiconductor layer in the second organic solvent is less than or equal to 1 mg/m L.

In some embodiments, the semiconductor layer includes at least one type I molecule, at least one type II molecule, at least one type III molecule, or combinations thereof, in which the at least one type I molecule has a structure of any one of following formula (1) to formula (11):

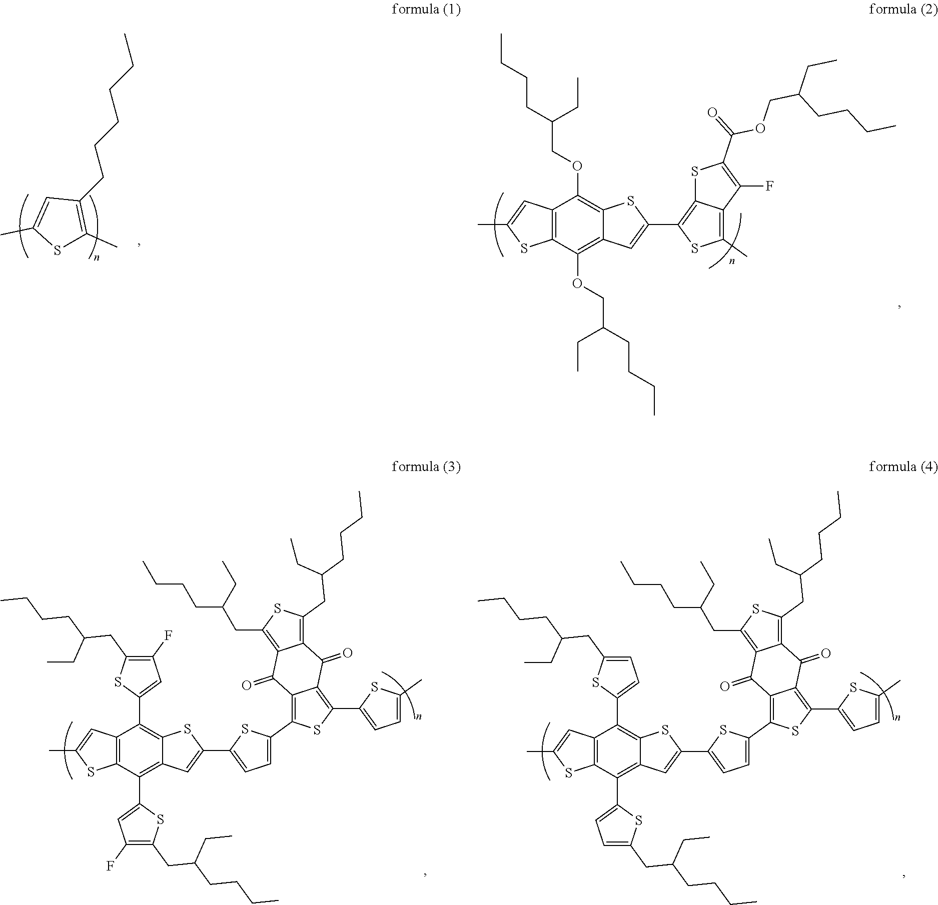

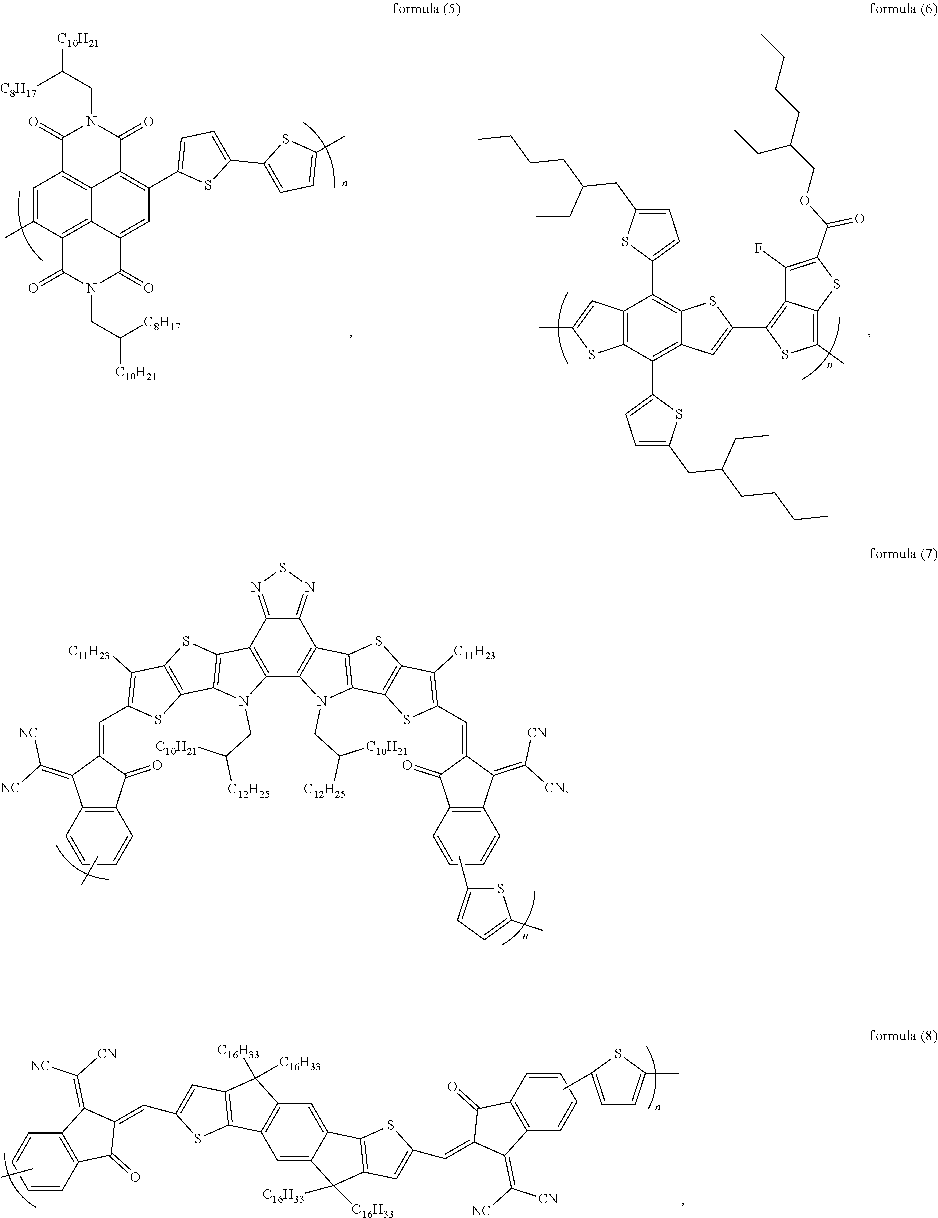

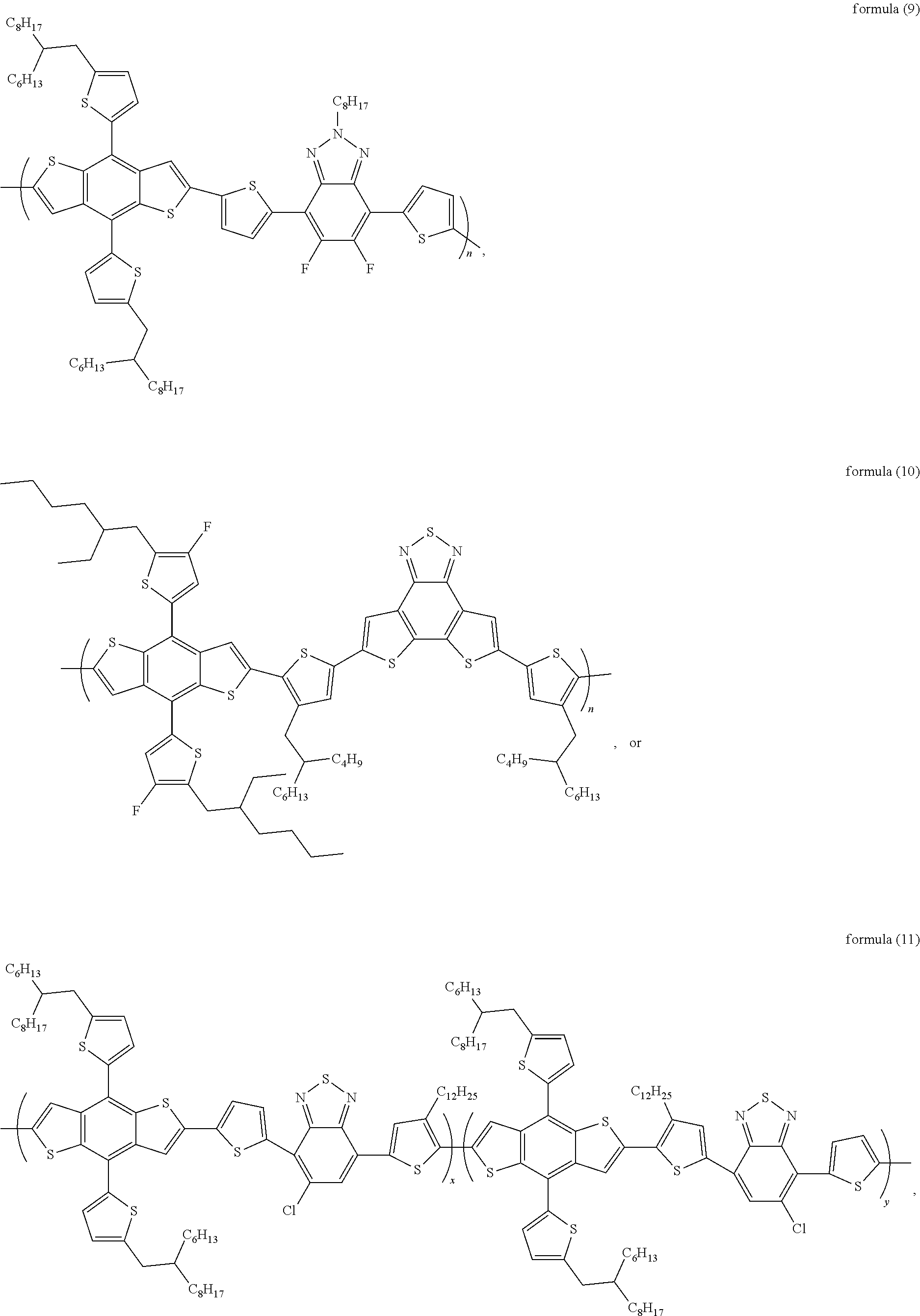

the at least one type II molecule has a structure of any one of following formula (12) to formula (16):

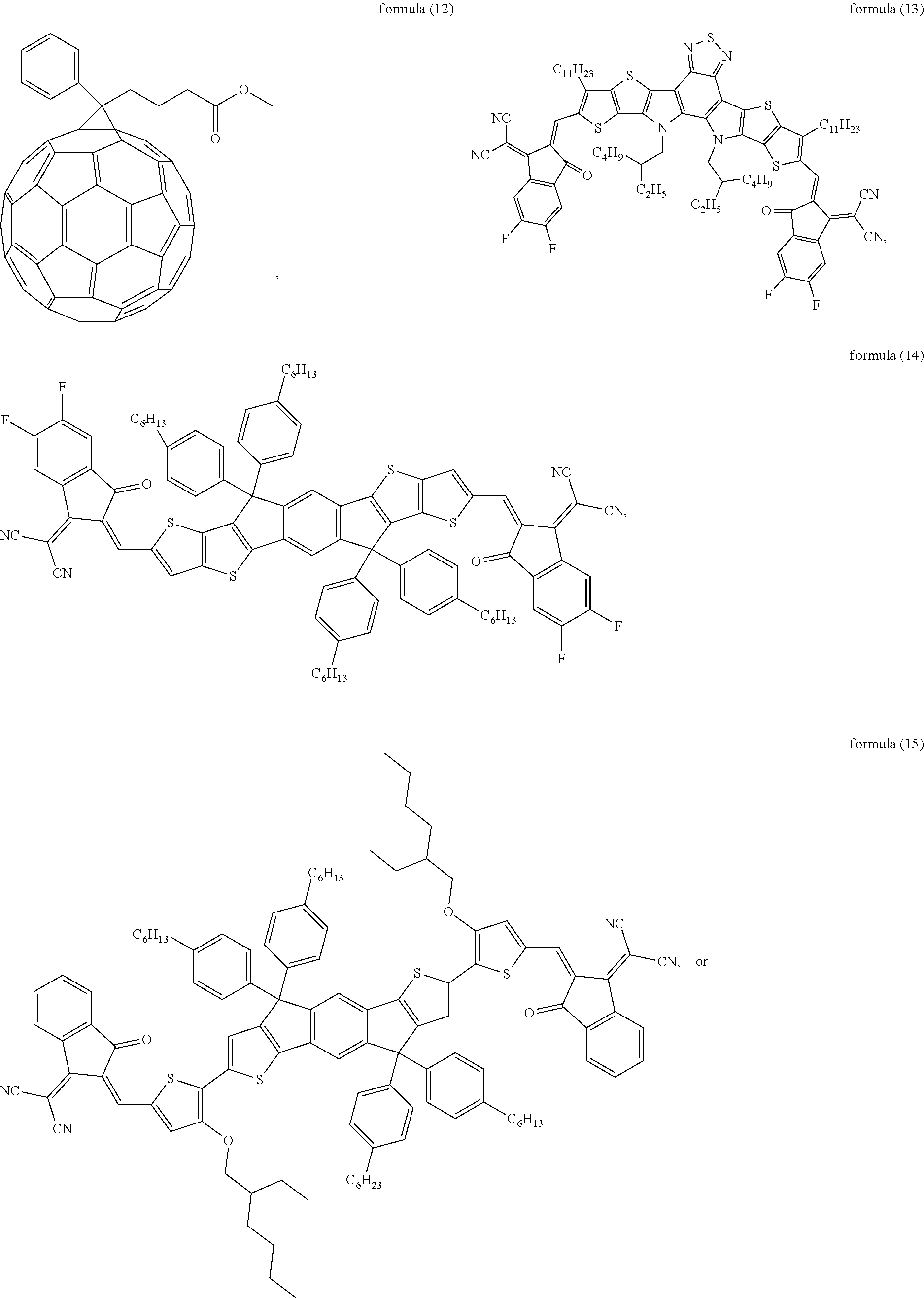

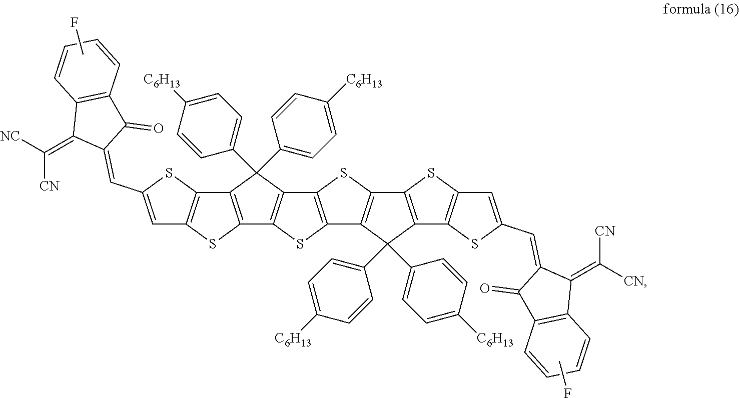

and the at least one type III molecule has a structure of following formula (17):

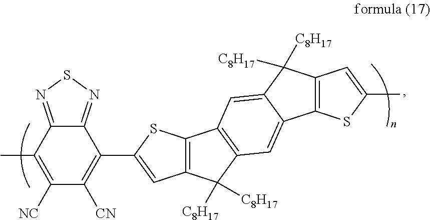

in which n is between 1 and 500, x and y are mole fractions respectively, and a sum of x and y is 1.

In some embodiments, the first organic solvent includes chloroform, chlorobenzene, o-dichlorobenzene, 1,2,4-trichlorobenzene, o-xylene, toluene, tetralin, tetrahydrofuran, dichloromethane, or combinations thereof.

In some embodiments, the second organic solvent includes n-heptane, methanol, 2-propanol, 1-butanol, ethanol, water, or combinations thereof.

In some embodiments, when the semiconductor layer includes the at least one type I molecule, the first organic solvent includes chloroform, chlorobenzene, o-dichlorobenzene, 1,2,4-trichlorobenzene, o-xylene, toluene, tetralin, tetrahydrofuran, dichloromethane, or combinations thereof, and the second organic solvent includes n-heptane, methanol, 2-propanol, 1-butanol, ethanol, water, ethyl acetate, acetone, or combinations thereof.

In some embodiments, when the semiconductor layer includes the at least one type II molecule, the first organic solvent includes chloroform, chlorobenzene, o-dichlorobenzene, 1,2,4-trichlorobenzene, o-xylene, toluene, tetralin, tetrahydrofuran, dichloromethane, ethyl acetate, acetone, or combinations thereof, and the second organic solvent includes n-heptane, methanol, 2-propanol, 1-butanol, ethanol, water, or combinations thereof.

In some embodiments, when the semiconductor layer includes the at least one type III molecule, the first organic solvent includes chloroform, chlorobenzene, o-dichlorobenzene, 1,2,4-trichlorobenzene, o-xylene, toluene, tetralin, tetrahydrofuran, dichloromethane, ethyl acetate, or combinations thereof, and the second organic solvent includes n-heptane, methanol, 2-propanol, 1-butanol, ethanol, water, acetone, or combinations thereof.

In some embodiments, a volume ratio of the first organic solvent to the second organic solvent is between 5:1 and 50:1.

In some embodiments, the method further includes after patterning the semiconductor layer, washing the semiconductor layer that is patterned with the second organic solvent to remove the first organic solvent.

In some embodiments, the method further includes before forming the photoresist layer, forming a protection layer on the semiconductor layer.

In some embodiments, the protection layer includes the hydrophilic polymer or a low surface energy material

In some embodiments, the method further includes before forming the protection layer, forming a release layer on the semiconductor layer.

In some embodiments, the release layer includes a low surface energy material.

In some embodiments, the method further includes when dissolving the exposed region of the semiconductor layer, spraying the solution onto the semiconductor layer, spinning coating the solution onto the semiconductor layer, or soaking the semiconductor layer into the solution.

In some embodiments, the method further includes after dissolving the exposed region of the semiconductor layer, removing the patterned photoresist layer.

### BRIEF DESCRIPTION OF THE DRAWINGS

Aspects of the present disclosure are best understood from the following detailed description when reading with the accompanying figures. It is noted that, in accordance with the standard practice of the industry, various features are not drawn to scale. In fact, the dimensions of the various features may be arbitrarily increased or reduced for clarity of discussion.

FIG. 1 is a flowchart of a method of patterning semiconductor layer according to some embodiments of the present disclosure.

FIGS. 2 to 7 are schematic diagrams of the intermediate stages in patterning semiconductor layer according to some embodiments of the present disclosure.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact.

In addition, spatially relative terms, such as below and above, etc., may be used in the present disclosure to describe the relationship of one element or feature to another element or feature in the figures. Besides the orientation depicted in the figures, spatially relative terms may encompass different orientations of the device in use or operation. For example, the device may be otherwise oriented (e.g., rotated 90 degrees or otherwise) and the spatially relative terms of the present disclosure can be interpreted accordingly. In the present disclosure, unless otherwise indicated, the same element numbers in different figures refer to the same or similar elements formed from the same or similar materials by the same or similar methods.

The present disclosure relates to a method of patterning semiconductor layer. The method includes the following operations. A semiconductor layer is formed on a substrate. A photoresist layer is formed on the semiconductor layer. The photoresist layer is patterned to form an opening that exposes an exposed region of the semiconductor layer in the photoresist layer. The exposed region of the semiconductor layer is dissolved with a solution to pattern the semiconductor layer, in which the solution includes a first organic solvent and a second organic solvent, a solubility of the semiconductor layer in the first organic solvent is greater than 1 mg/mL, and a solubility of the semiconductor layer in the second organic solvent is less than or equal to 1 mg/mL. The method of patterning semiconductor layer of the present disclosure uses the first organic solvent and the second organic solvent which have different solubility to the semiconductor layer to pattern the semiconductor layer. Compared with the conventional wet etching using the acid or alkaline solution, the method of the present disclosure reduces the damage to the semiconductor layer and preserves the characteristics of the semiconductor layer. Compared with the conventional dry etching using vacuum equipment, the method of the present disclosure simplifies the process and is easier to be implemented. The method of patterning semiconductor layer of the present disclosure is described in detail based on the embodiments in the following paragraphs.

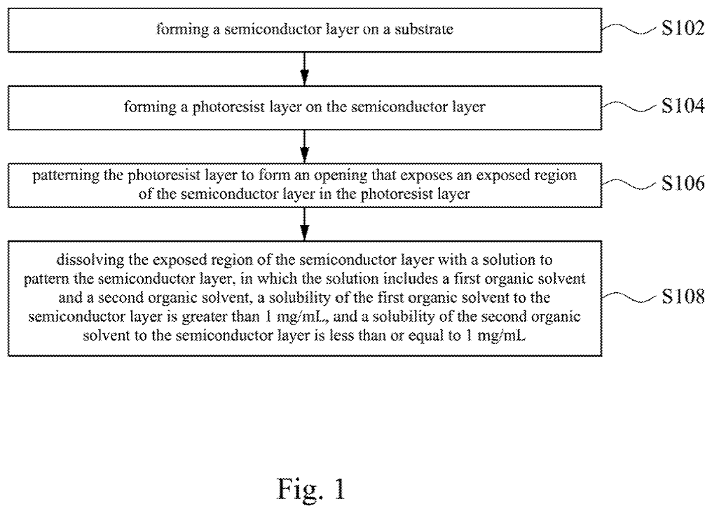

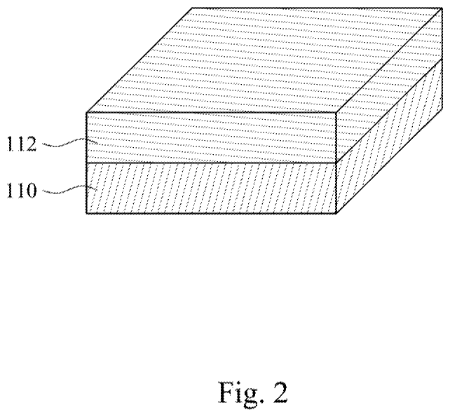

FIG. 1 is a flowchart of a method of patterning semiconductor layer according to some embodiments of the present disclosure. FIGS. 2 to 7 are schematic diagrams of the intermediate stages in patterning semiconductor layer according to some embodiments of the present disclosure. When reading the flowchart of the method in FIG. 1, please also refer to the schematic diagrams of FIGS. 2 to 7.

In FIG. 1, the method of patterning semiconductor layer includes operation S102, corresponding to FIG. 2, to form a semiconductor layer 112 on a substrate 110. In some embodiments, the semiconductor layer 112 is formed on the substrate 110 by spin coating. In some embodiments, the substrate 110 includes but is not limited to a flexible polyethylene terphthalate (PET), a flexible poly ethylene naphthalate (PEN), a flexible polyimide (PI), or combinations thereof. In some embodiments, the substrate 110 includes but is not limited to an inflexible glass substrate, an inflexible wafer substrate, or a combination thereof. In some embodiments, the substrate 110 includes an electrode. In some embodiments, the semiconductor layer 112 includes a soluble organic semiconductor material that is not limited to, for example, a conjugated polymer, a conjugated small molecule, a fullerene derivative, a non-fullerene receptor, or combinations thereof. To implement the present disclosure, a type I molecule, a type II molecule, and a type III molecule are provided in detail as illustrative examples in the following paragraphs. It is noted that these are examples and it is not intended to be the limitation of the present disclosure. As long as using the method of patterning semiconductor layer provided by the present disclosure is within the scope of the present disclosure. Specifically, the semiconductor layer 112 includes at least one type I molecule, at least one type II molecule, at least one type III molecule, or combinations thereof, for example, a combination of one type I molecule and one type II molecule, a combination of one type II molecule and one type III molecule, a combination of one type I molecule and one type III molecule, a combination of two type I molecules, a combination of two type II molecules, a combination of two type III molecules, and so on. The type I molecule, the type II molecule, and the type III molecule are divided based on solubility (see below for details). In some embodiments, the type I molecule, the type II molecule, and the type III molecule are photosensitive, such as having excellent photoelectric conversion efficiency, thereby being novel materials in semiconductor electronic components. However, limited by the obtainable patterning methods (e.g., wet etching using acid or alkaline solution or dry etching under vacuum environment), it is hard to pattern these materials or to meet the economic cost.

Next, the type I molecule is discussed in detail. The type I molecule has a structure of any one of the following formula (1) to formula (11):

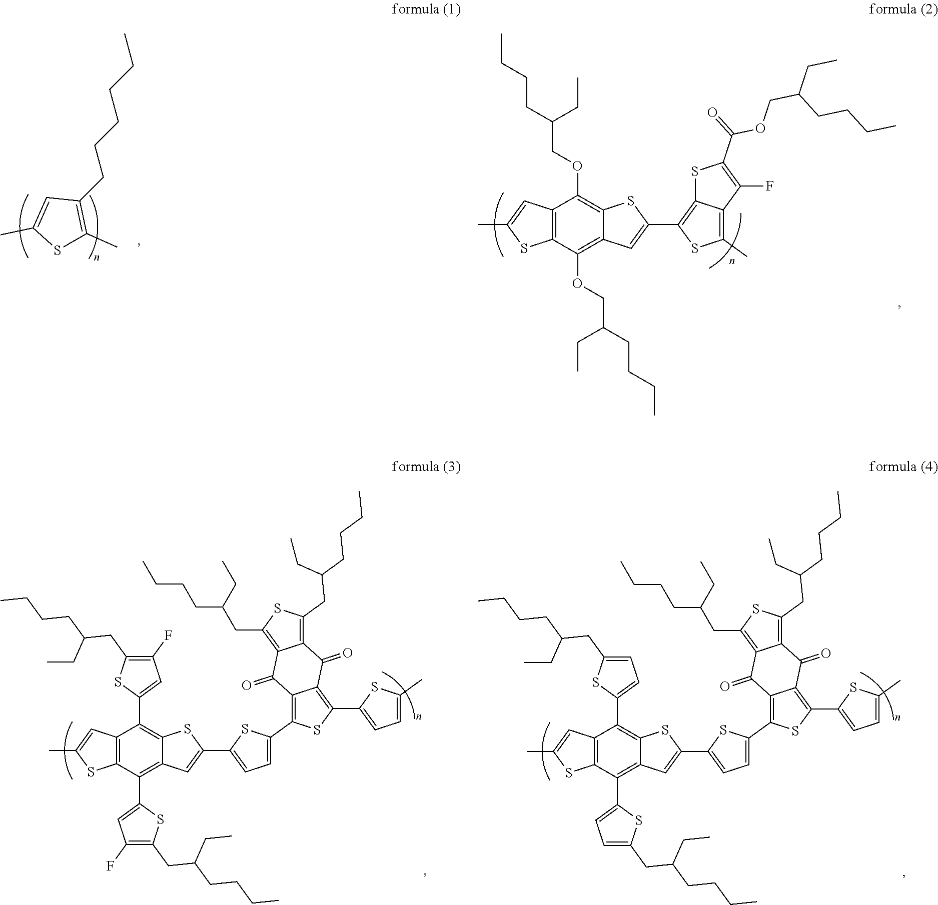

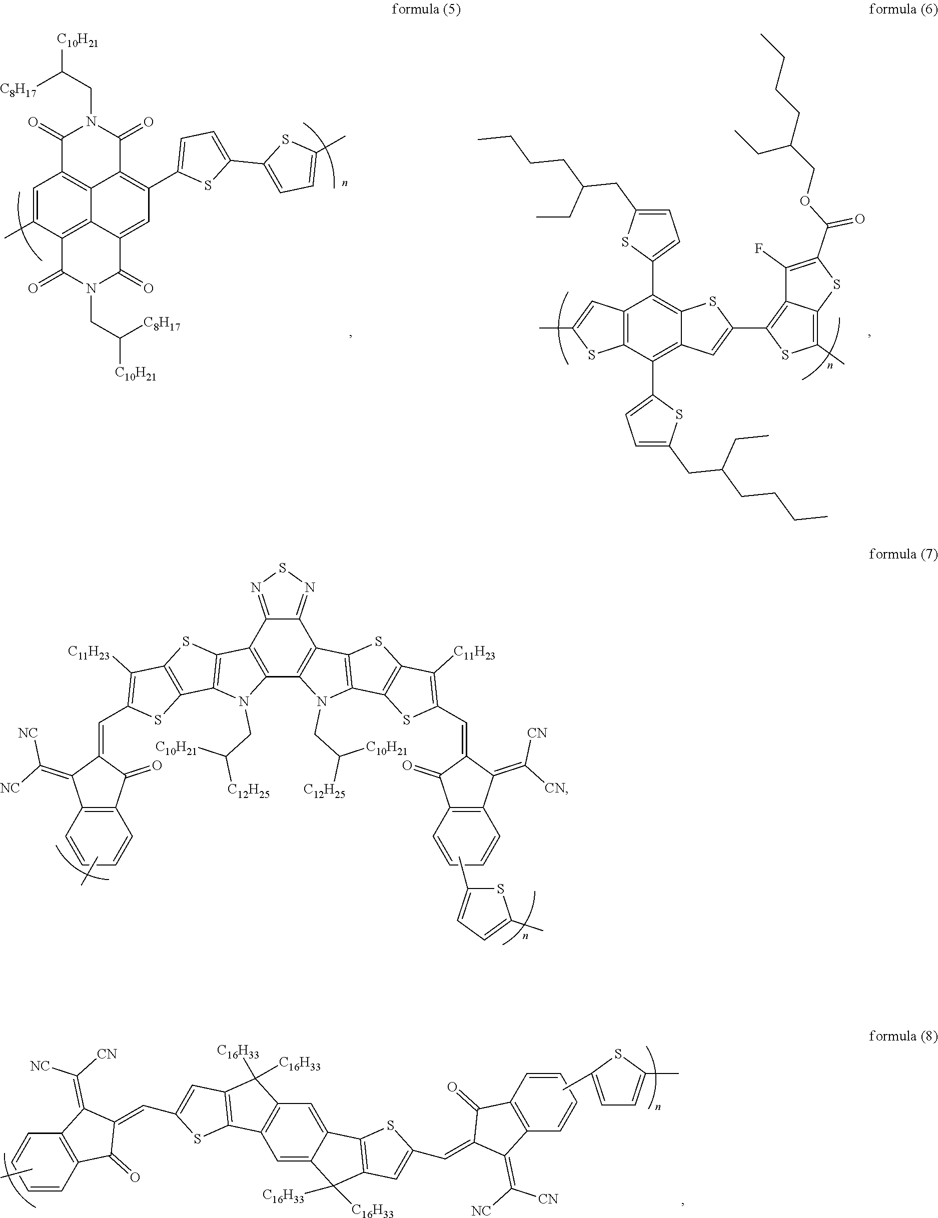

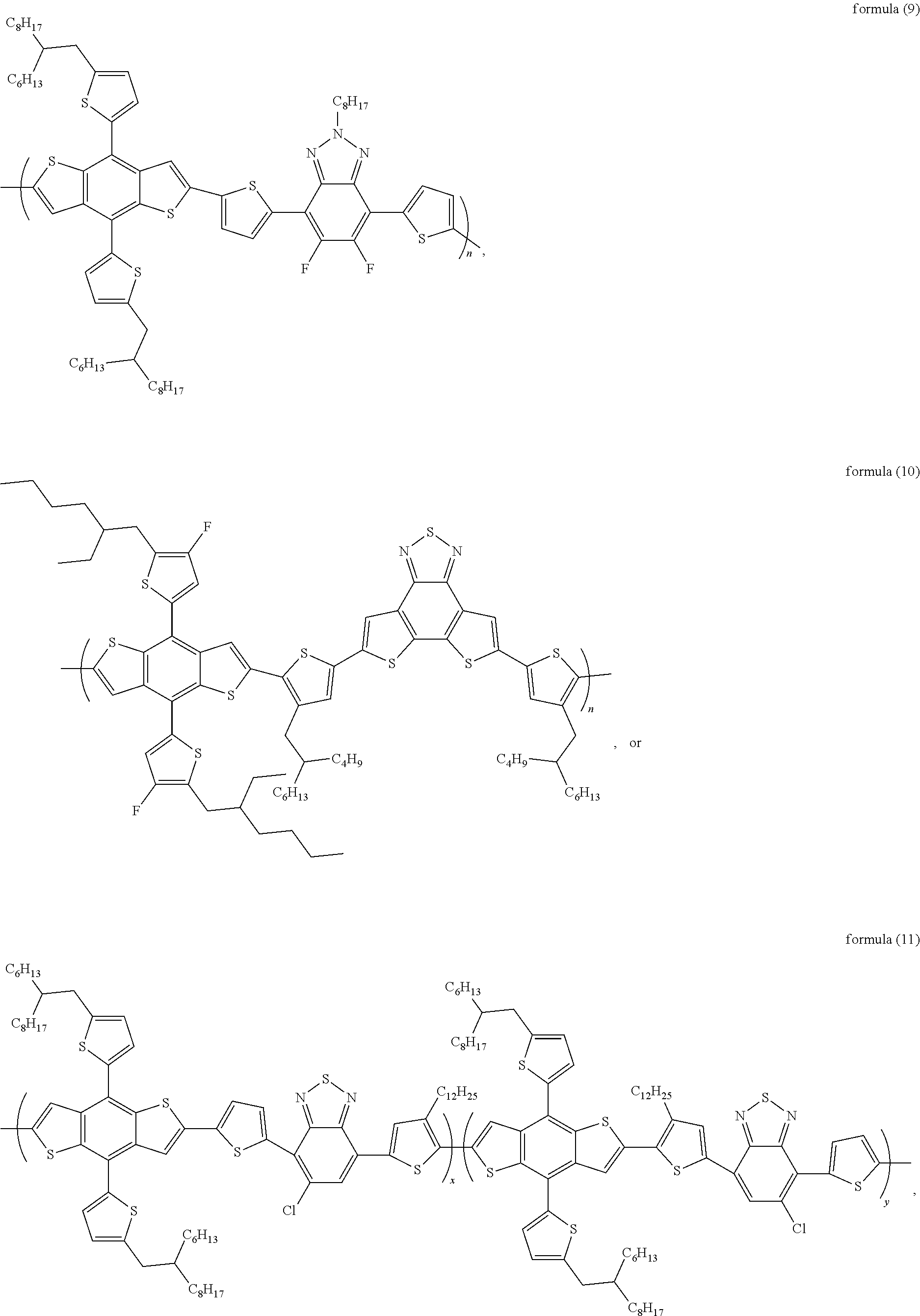

in which n is between 1 and 500, x and y each is a mole fraction, and a sum of x and y is 1. Specifically, formula (1) is poly(3-hexylthiophene-2,5-diyl) (P3HT), formula (2) is poly({4,8-bis[(2-ethylhexyl)oxy]benzo[1,2-b:4,5-b′]dithiophene-2,6-diyl}{3-fluoro-2-[(2-ethylhexyl)carbonyl]thieno[3,4-b]thiophenediyl]}) (PTB7), formula (3) is poly[{4,8-bis[5-(2-ethylhexyl)-4-fluoro-2-thienyl]benzo[1,2-b:4,5-bldithiophene-2, 6-diyl]-2,5-thiophenediyl[5,7-bis(2-ethylhexyl)-4,8-dioxo-4H,8H-benzo[1,2-c:4,5-c′]dithiophene-1,3-diyl]-2,5-thiophenediyl] (PM6), formula (4) is poly[[4,8-bis[5-(2-ethylhexyl)-2-thienyl]benzo[1,2-b:4,5-bldithiophene-2,6-diyl]-2,5-thioph enediyl[5,7-bis(2-ethylhexyl)-4,8-dioxo-4H,8H-benzo[1,2-c:4,5-c′]dithiophene-1,3-diyl]] (PBDB-T), formula (5) is poly{[N,N-bis(2-octyldodecyl)-naphthalene-1,4,5,8-bis(dicarboximide)-2,6-diyl]-alt-5,5′-(2,2′-bithiophene)}(N2200), formula (6) is poly([2,6′-4,8-di(5-ethylhexylthienyl)benzo[1,2-b;3,3-b]dithiophenel]{3-fluoro-2[(2-ethylhexyl)carbonyl]thieno[3,4-b]thiophenediyl}) (PTB7-Th), formula (7) is poly[[12,13-bis(2-decyltetradecyl)-12,13-dihydro-3,9-diundecylbisthieno[2″, 3″:4′, 5′]thieno[2′, 3′:4,5]pyrrolo[3,2-g] [2′, 3′-g][2,1,3]benzothiadiazole-2,10-diyl]met hylidyne[1-(dicyanomethylene)-1,3-dihydro-3-oxo-2H-inden-yl-2-ylidene]-2,5-thi ophenediyl[1-(dicyanomethylene)-1,3-dihydro-3-oxo-2H-inden-yl-2-ylidene]meth ylidyne] (PJ1), formula (8) is poly{2,2′4(2Z,2′Z)-((4,4,9,9-tetrahexadecyl-4,9-dihydro-s-indaceno[1,2-b:5,6-b′]dithiophene-2,7-diAbis(methanylylidene))bis(3-oxo-2,3-dihydro-1H-indene-2,1-diylidene))dimalononitrile-5,5′-diyl-alt-thiophen-2,5-diyl}(PZ1), formula (9) is poly[(5,6-difluoro-2-octyl-2H-benzotriazole-4,7-diyl)-2,5-thiophenediyl[4,8-bis[5-(2-hexyldecyl)-2-thienyl]benzo[1,2-b:4,5-bldithiophe ne-2,6-diyl]-2,5-thiophenediyl] (J51), formula (10) is poly[(2,6-(4,8-bis(5-(2-ethylhexyl-3-fluoro)thiophen-2-yl)-benzo[1,2-b:4,5-b]dithiophene))-alt-5,5′-(5,8-b is (4-(2-butyloctyl)thiophen-2-yl)dithieno[3′,2′:3,4;2″,3″:5,6]benzo[1,2-c][1,2,5]thia diazole)] (D18), and formula (11) is poly(7-(4-dodecyl-thiophen-2-yl)-4-(thiophen-2-yl)-5-chloro-benzo[1,2,5]thiadiazole)-alt-ran-(4,8-bis(5-(2-hexyldecyl)-thiophene-2-yl)-benzodithiophene (RP 1).

Next, the type II molecule is discussed in detail. The type II molecule has a structure of any one of the following formula (12) to formula (16):

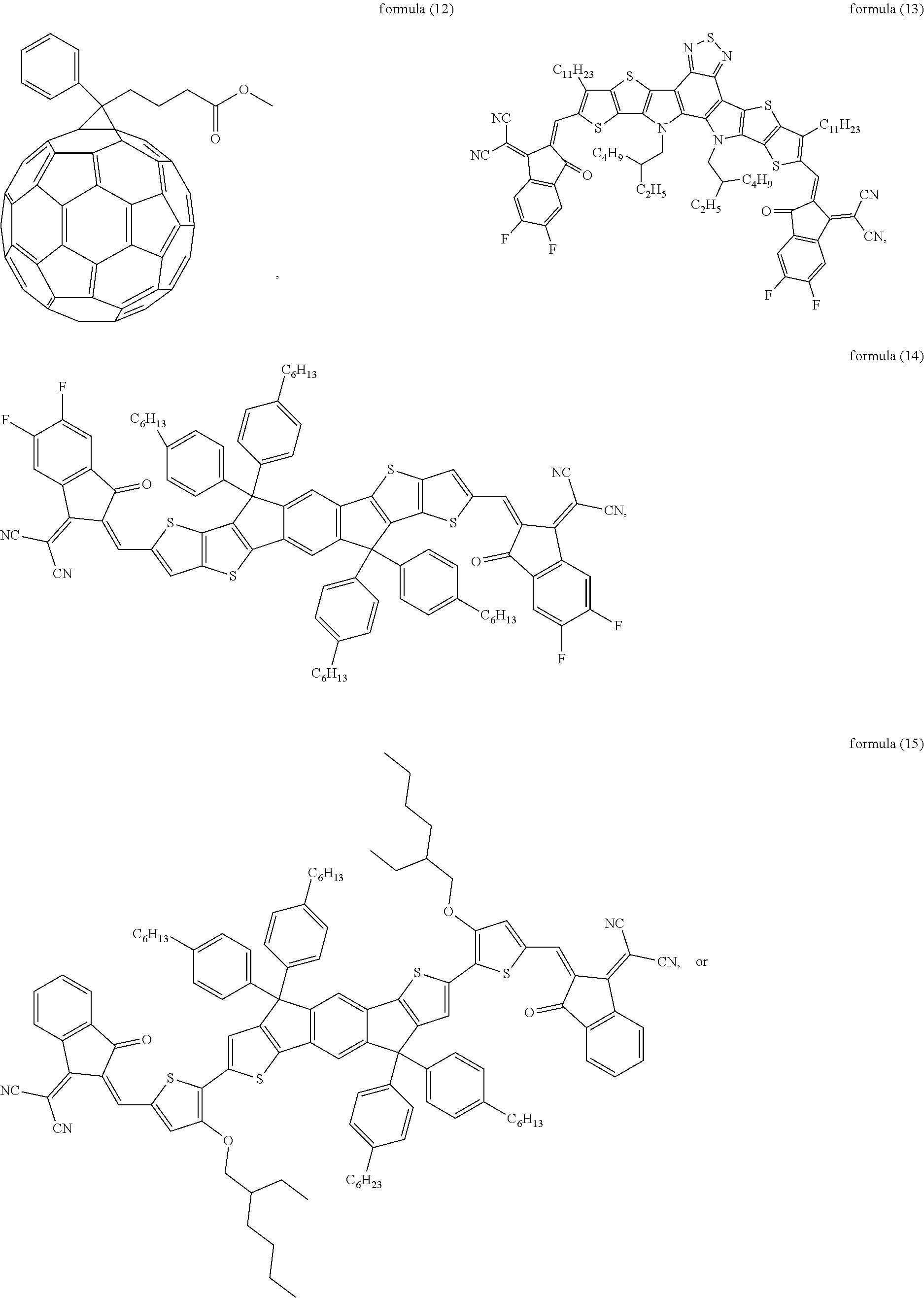

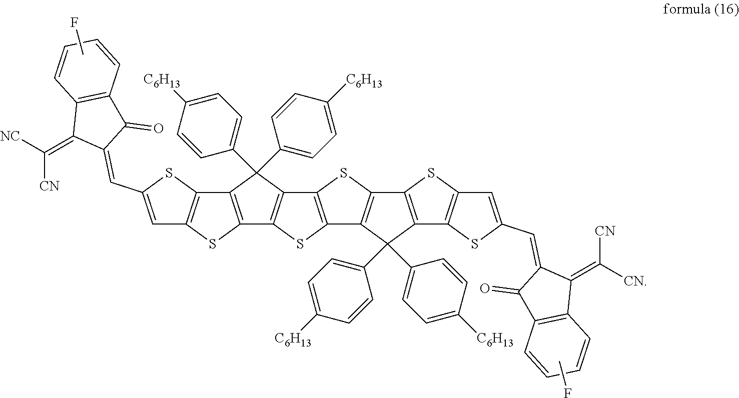

Specifically, formula (12) is [6,6]-Phenyl-C61-butyric acid methyl ester (PCBM), formula (13) is 2,2′4(2Z,2′Z)-((12,13-bis(2-ethylhexyl)-3,9-diundecyl-12,13-dihydro-[1,2,5]thiadiazolo[3,4-e]thieno[2″,3″:4′,5′]thieno[2′,3′:4,5]pyrrolo[3,2-g]thieno[2′,3′:4,5]thi eno[3,2-b]indole-2,10-diyl)bis(methanylylidene))bis(5,6-difluoro-3-oxo-2,3-dihydr o-1H-indene-2,1-diylidene))dimalononitrile (Y6), formula (14) is 2,2′-[[6,6,12,12-Tetrakis(4-hexylphenyI)-6,12-dihydrodithieno[2,3-d:2′,3′-d′]-s-ind aceno[1,2-b:5,6-b′]dithiophene-2,8-diyl]bis[methylidyne(5,6-difluoro-3-oxo-1H-in dene-2,1(3H)-diylidene)]]bis[propanedinitrile] (IT-4F), formula (15) is 2,2′-[[4,4,9,9-tetrakis(4-hexylphenyI)-4,9-dihydro-s-indaceno[1,2-b:5,6-b′]dithiop hene-2,7-diyl]bis[[4-[(2-ethylhexyl)oxy]-5,2-thiophenediyl]-(Z)-methylidyne(3-oxo-1H-indene-2,1(3H)-diylidene)]]bis-propanedinitrile,2,2′-((2Z,2′Z)-((5,5′-bis(4,4,9,9-tetrakis(4-hexylphenyI)-4,9-dihydro-s-indaceno[1,2-b:5,6-b′]dithiophene-2,7-di yl)bis(44(2-ethylhexyl)oxy)thiophene-5,2-diyl))bis(methanylylidene))bis-(3-oxo-2,3-dihydro-1H-indene-2,1-diylidene))dimalononitrile (IEICO), and formula (16) is 2,2′-[[6,6,12,12-tetrakis(4-hexylphenyI)-6,12-dihydrothieno[2″,3″:4′,5′]thieno[3′,2′:4,5]cyclopenta[1,2-b]thieno[2″′,3′″:4″,5″]thieno[2″,3″:3′,4′]cyclopenta[1′,2′:4,5]thi eno[2,3-d]thiophene-2,8-diyl]bis[methylidyne(fluoro-3-oxo-1H-indene-2,1(3H)-di ylidene)]]bis[propanedinitrile] (FOIC).

Next, the type III molecule is discussed in detail. The type III molecule has a structure of the following formula (17):

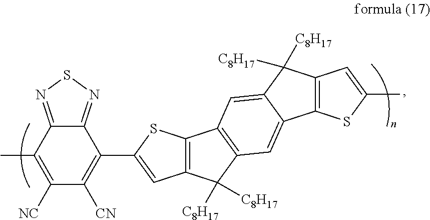

in which n is between 1 and 500. Specifically, formula (17) is poly(5,6-dicyano-2,1,3-benzothiadiazole-alt-indacenodithiophene) (DCNBT-IDT).

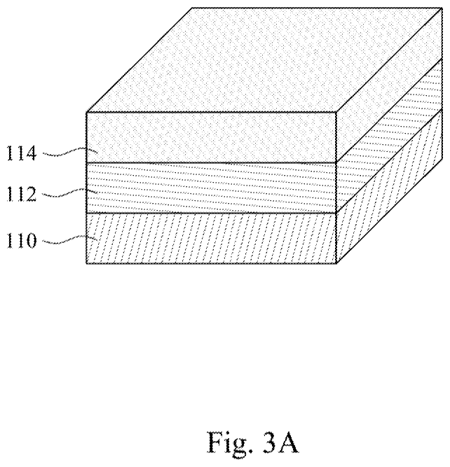

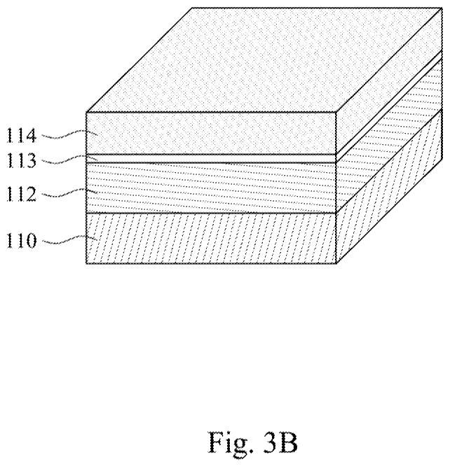

Continue to refer to the method of patterning semiconductor layer in FIG. 1. Proceed to operation S104 after operation S102, corresponding to FIGS. 3A to 3B, to form the photoresist layer 114 on the semiconductor layer 112. The photoresist layer 114 is used to define the patterns of the semiconductor layer 112 in the subsequent processes. In some embodiments, before forming the photoresist layer 114, the method of patterning semiconductor layer of the present disclosure further includes forming a protection layer 113 on the semiconductor layer 112. The protection layer 113 is between the semiconductor layer 112 and the photoresist layer 114 and does not have chemical reactions with the semiconductor layer 112, thereby protecting the semiconductor layer 112 and reducing the damage to the semiconductor layer 112 throughout the process. For example, if the material of the photoresist layer 114 has chemical reactions with the material of the semiconductor layer 112, the protection layer 113 can protect the semiconductor layer 112. In addition, the protection layer 113 of the present disclosure can be patterned together with the photoresist layer 114 so that the protection layer 113 does not affect the photoresist layer 114 to define the pattern of the semiconductor layer 112 in the subsequent process. In some embodiments, the protection layer 113 includes a hydrophilic polymer or a low surface energy material. For example, the hydrophilic polymer includes polyvinyl alcohol, polyvinylpyrrolidone, polystyrene sulfonic acid, or combinations thereof. For example, the low surface energy material includes a fluoro-containing polymer or oligomer, such as polytetrafluoroethylene, polyvinylidene difluoride, or a combination thereof. The hydrophilic polymer and the low surface energy material are not limited to the above-mentioned materials, as long as the materials that do not have the chemical reaction with the semiconductor layer 112 and can be patterned together with the photoresist layer 114 are intended to be included in the scope of the present disclosure. In some embodiments, before forming the protection layer 113, the method of patterning semiconductor layer of the present disclosure further includes forming a release layer (not shown in the figures) on the semiconductor layer 112. The release layer is between the semiconductor layer 112 and the protection layer 113 and does not have chemical reactions with the semiconductor layer 112. In addition, the release layer of the present disclosure can be patterned together with the photoresist layer 114 so that the release layer does not affect the photoresist layer 114 to define the pattern of the semiconductor layer 112 in the subsequent process. Furthermore, the release layer of the present disclosure makes the photoresist layer 114 and the protection layer 113 detach more easily from the semiconductor layer 112. In some embodiments, the release layer includes a low surface energy material, such as a fluoro-containing polymer or oligomer, for example, polytetrafluoroethylene, polyvinylidene difluoride, or a combination thereof. The low surface energy material is not limited to the above-mentioned materials, as long as the materials that do not have the chemical reaction with the semiconductor layer 112 and can make the photoresist layer 114 and the protection layer 113 detach more easily from the semiconductor layer 112 are intended to be included in the scope of the present disclosure.

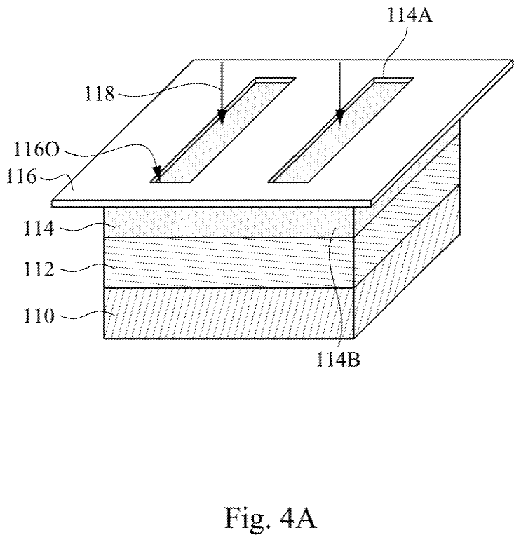

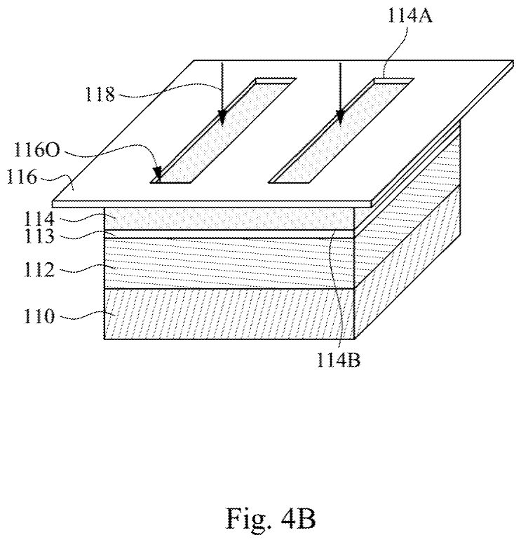

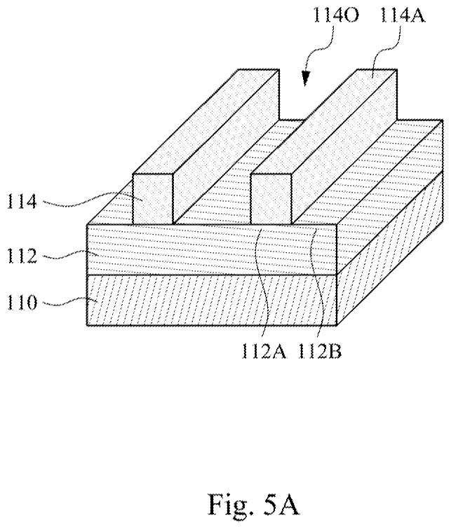

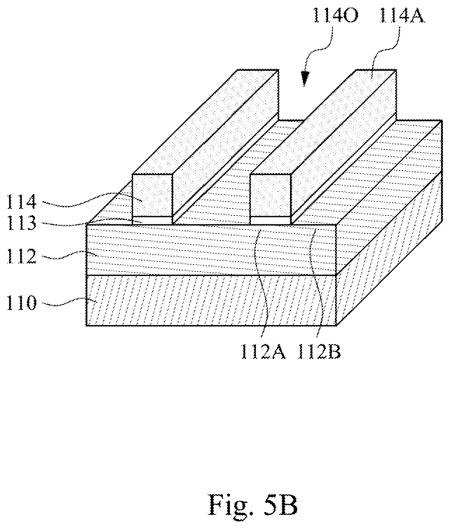

Continue to refer to the method of patterning semiconductor layer in FIG. 1. Proceed to operation S106 after operation S104, corresponding to FIGS. 4A to 5B, to pattern the photoresist layer 114 to forming an opening 1140 that exposes an exposed region 112B of the semiconductor layer 112 in the photoresist layer 114. Specifically, a mask 116 as shown in FIGS. 4A to 4B covers the photoresist layer 114. The mask 116 has an opening pattern 1160 that exposes a portion 114A of the photoresist layer 114. The unexposed portion covered by the mask 116 is a remaining portion 114B of the photoresist layer 114. Later, a light source 118 (e.g., ultraviolet light) incidents the mask 116. The portion 114A of the photoresist layer 114 cures because of the exposure to the light source 118 so that it remains on the semiconductor layer 112. However, the remaining portion 114B of the photoresist layer 114 is not cured because it is covered by the mask 116 and not exposed to the light source 118 so that it is removed from the semiconductor layer 112. As a result, the opening 1140 in the photoresist layer 114 is formed, as shown in FIGS. 5A to 5B. In FIGS. 5A to 5B, the patterned photoresist layer 114 defines the exposed region 112B and a unexposed region 112A in the semiconductor layer 112, in which the opening 1140 of the photoresist layer 114 exposes the exposed region 112B of the semiconductor layer 112 and the portion 114A of the photoresist layer 114 covers the unexposed region 112A of the semiconductor layer 112. It is noted that the above-mentioned operation can further include the protection layer 113 (as shown in FIGS. 4B and 5B) and the release layer (not shown in the figures). With the incident of the light source 118 (e.g., ultraviolet light) to the mask 116, the protection layer 113 and the release layer that are under the portion 114A of the photoresist layer 114 cure and remain on the semiconductor layer 112. When removing the uncured remaining portion 114B of the photoresist layer 114, the uncured protection layer 113 and release layer are removed together with the remaining portion 114B of the photoresist layer 114. In other words, the protection layer 113 and the release layer are patterned together with the photoresist layer 114. However, in some embodiments, the pattern processes of the photoresist layer 114, the protection layer 113, and the release layer can be implemented independently. For example, the photoresist layer 114 may be patterned first and later the protection layer 113 and the release layer in sequence.

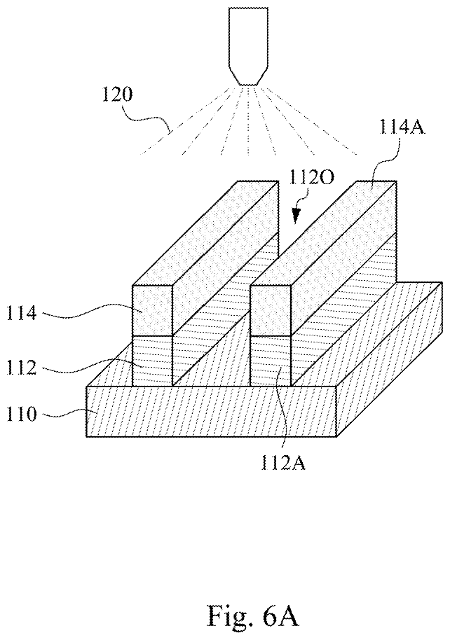

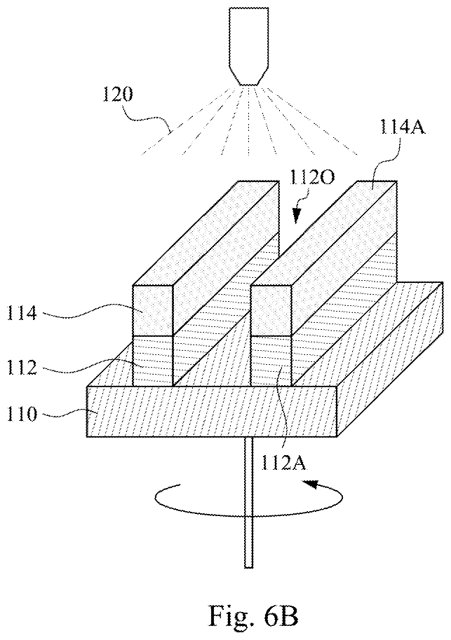

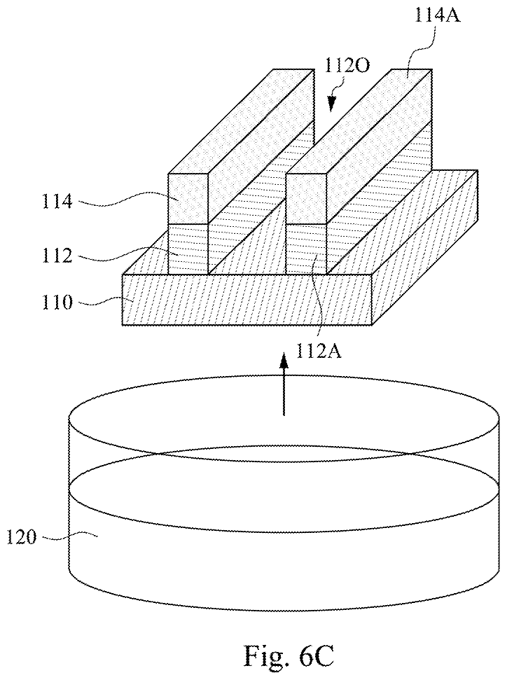

Continue to refer to the method of patterning semiconductor layer in FIG. 1. Proceed to operation S108 after operation S106, corresponding to FIGS. 6A to 6C, to use a solution 120 to dissolve the exposed region 112B of the semiconductor layer 112 to pattern the semiconductor layer 112. The solution 120 includes a first organic solvent (not shown in the figures) and a second organic solvent (not shown in the figures). The solubility of the semiconductor layer 112 in the first organic solvent is greater than 1 mg/mL, for example, between 1.01 mg/mL and 100 mg/mL (e.g., 1.01 mg/mL, 2 mg/mL, 4.99 mg/mL, 5 mg/mL, 10 mg/mL, 50 mg/mL, 100 mg/mL, and so on). The solubility of the semiconductor layer 112 in the second organic solvent is less than or equal to 1 mg/mL, for example, between 0 mg/mL to 1 mg/mL (e.g., 0 mg/mL, 0.01 mg/mL, 0.1 mg/mL, 1 mg/mL, and so on). The solution 120 including the first organic solvent and the second organic solvent dissolves the exposed region 112B of the semiconductor layer 112 not covered by the portion 114A of the photoresist layer 114 to form an opening 1120 in the semiconductor layer 112. On the contrary, the unexposed region 112A of the semiconductor layer 112 covered by the portion 114A of the photoresist layer 114 is not dissolved. In some embodiments, the first organic solvent is more than the second organic solvent in the solution 120. In some embodiments, a volume ratio of the first organic solvent to the second organic solvent is between 5:1 and 50:1, for example, 5:1, 10:1, 20:1, 50:1, and so on. The volume ratio of the first organic solvent to the second organic solvent in the above-mentioned region not only dissolves the semiconductor layer 112 but also optimally patterns the semiconductor layer 112. For example, the semiconductor layer 112 is not overly dissolved (e.g., the sidewalls of the unexposed region 112A of the semiconductor layer 112 are dissolved) and there is no insufficient dissolution (e.g., some of the exposed region 112B in the semiconductor layer 112 is not dissolved). In some embodiments, the detailed operation S108 includes, as shown in FIG. 6A, spraying the solution 120 onto the semiconductor layer 112 to dissolve the exposed region 112B. In some embodiments, the detailed operation S108 includes, as shown in FIG. 6B, spinning coating the solution 120 onto the semiconductor layer 112 to dissolve the exposed region 112B. In some embodiments, the detailed operation S108 includes, as shown in FIG. 6C, soaking the semiconductor layer 112 into the solution 120. After removing the semiconductor layer 112 from the solution 120, the exposed region 112B of the semiconductor layer 112 is dissolved. It is noted that the protection layer and the release layer are not drawn in FIGS. 6A to 6C.

Details of the first organic solvent, the second organic solvent, and the solubility of the semiconductor layer 112 in the first organic solvent and the second organic solvent are discussed in Table 1. In some embodiments, the first organic solvent includes chloroform (CF), chlorobenzene (CB), o-dichlorobenzene (DCB), 1,2,4-trichlorobenzene (TCB), o-xylene, toluene, tetralin, tetrahydrofuran (THF), dichloromethane (DCM), or combinations thereof. The solubility of the semiconductor layer 112 in the first organic solvent is greater than 1 mg/mL, for example, between 1.01 mg/mL and 100 mg/mL (e.g., 1.01 mg/mL, 2 mg/mL, 4.99 mg/mL, 5 mg/mL, 10 mg/mL, 50 mg/mL, 100 mg/mL, and so on). The solubility of the semiconductor layer 112 including the type I molecule (formula (1) to formula (11)), the type II molecule (formula (12) to formula (16)), and the type III molecule (formula (17)) are indicated as O and Δ in Table 1, where O represents the solubility greater than or equal to 5 mg/mL, for example, between 5 mg/mL and 100 mg/mL (e.g., 5 mg/mL, 10 mg/mL, 50 mg/mL, 100 mg/mL, and so on), and Δ represents the solubility between 1.01 mg/mL to 4.99 mg/mL (e.g., 1.01 mg/mL, 2 mg/mL, 4.99 mg/mL, and so on). In some embodiments, the second organic solvent includes n-heptane, methanol, 2-propanol, 1-butanol, ethanol, water, or combinations thereof. The solubility of the semiconductor layer 112 in the second organic solvent is less than or equal to 1 mg/mL, for example, between 0 mg/mL and 1 mg/mL (e.g., 0 mg/mL, 0.01 mg/mL, 0.1 mg/mL, 1 mg/mL, and so on), which are indicated as X for the semiconductor layer 112 including the type I molecule (formula (1) to formula (11)), the type II molecule (formula (12) to formula (16)), and the type III molecule (formula (17)) in Table 1. Using all the above-mentioned first organic solvent and second organic solvent can implement the method of patterning semiconductor layer of the present disclosure. For example, when the semiconductor layer 112 includes formula (1) and formula (12) (i.e., P3HT and PCBM), the first organic solvent can be o-xylene and the second organic solvent can be n-heptane.

However, It is noted that, in Table 1, ethyl acetate and acetone are the second organic solvents for the type I molecule and the solubility is less than or equal to 1 mg/mL, which are represented by X to indicate the solubility between 0 mg/mL to 1 mg/mL (e.g., 0 mg/mL, 0.01 mg/mL, 0.1 mg/mL, 1 mg/mL, and so on). Ethyl acetate and acetone are the first organic solvents for the type II molecule and the solubility is greater than 1 mg/mL, which are represented by Δ to indicate the solubility between 1.01 mg/mL to 4.99 mg/mL (e.g., 1.01 mg/mL, 2 mg/mL, 4.99 mg/mL, and so on). Ethyl acetate is the first organic solvent for the type III molecule and the solubility is greater than 1 mg/mL, which is represented by Δ to indicate the solubility between 1.01 mg/mL and 4.99 mg/mL (e.g., 1.01 mg/mL, 2 mg/mL, 4.99 mg/mL, and so on). However, acetone is the second organic solvent for the type III molecule and the solubility is less than or equal to 1 mg/mL, which is represented by X to Indicate the solubility between 0 mg/mL and 1 mg/mL (e.g., 0 mg/mL, 0.01 mg/mL, 0.1 mg/mL, 1 mg/mL, and so on). In other words, ethyl acetate and acetone are not applicable to all the combinations of the semiconductor layer 112. For example, when the semiconductor layer 112 includes formula (1) and formula (12) (i.e., P3HT and PCBM), although the solubility of the formula (12) in ethyl acetate is greater than 1 mg/mL, but the solubility of the formula (1) in ethyl acetate is less than or equal to 1 mg/mL, therefore, in this case, ethyl acetate is not the first organic solvent nor the second organic solvent. The same reason is applicable to acetone and will not be repeated in the explanation. For the above reasons, when the semiconductor layer 112 includes the at least one type I molecule, the first organic solvent includes chloroform, chlorobenzene, o-dichlorobenzene, 1,2,4-trichlorobenzene, o-xylene, toluene, tetralin, tetrahydrofuran, dichloromethane, or combinations thereof, and the second organic solvent includes n-heptane, methanol, 2-propanol, 1-butanol, ethanol, water, ethyl acetate, acetone, or combinations thereof. When the semiconductor layer 112 includes the at least one type II molecule, the first organic solvent includes chloroform, chlorobenzene, o-dichlorobenzene, 1,2,4-trichlorobenzene, o-xylene, toluene, tetralin, tetrahydrofuran, dichloromethane, ethyl acetate, acetone, or combinations thereof, and the second organic solvent includes n-heptane, methanol, 2-propanol, 1-butanol, ethanol, water, or combinations thereof. When the semiconductor layer 112 includes the at least one type III molecule, the first organic solvent includes chloroform, chlorobenzene, o-dichlorobenzene, 1,2,4-trichlorobenzene, o-xylene, toluene, tetralin, tetrahydrofuran, dichloromethane, ethyl acetate, or combinations thereof, and the second organic solvent includes n-heptane, methanol, 2-propanol, 1-butanol, ethanol, water, acetone, or combinations thereof.

TABLE 1

| | Formula | Formula | Formula | Formula | Formula | Formula | Formula | Formula | Formula |
|---|---|---|---|---|---|---|---|---|---|
| | (1) | (2) | (3) | (4) | (5) | (6) | (7) | (8). | (9). |
| CF | ○ | ○ | ○ | ○ | ○ | ○ | ○ | ○ | ○ |
| CB | ○ | ○ | ○ | ○ | ○ | ○ | ○ | ○ | ○ |
| DCB | ○ | ○ | ○ | ○ | ○ | ○ | ○ | ○ | ○ |
| TCB | ○ | ○ | ○ | ○ | ○ | ○ | ○ | ○ | ○ |
| o-Xylene | ○ | ○ | ○ | ○ | ○ | ○ | ○ | ○ | ○ |
| Toluene | ○ | ○ | ○ | ○ | ○ | ○ | ○ | ○ | ○ |
| Tetralin | ○ | ○ | ○ | ○ | ○ | ○ | ○ | ○ | ○ |
| THF | Δ | Δ | Δ | Δ | ○ | Δ | Δ | Δ | ○ |
| DCM | Δ | Δ | Δ | Δ | ○ | Δ | Δ | Δ | Δ |
| Ethyl | × | × | × | × | × | × | × | × | × |
| Acetate | | | | | | | | | |
| Acetone | × | × | × | × | × | × | × | × | × |
| n-Heptane | × | × | × | × | × | × | × | × | × |
| Methanol | × | × | × | × | × | × | × | × | × |
| 2-Propanol | × | × | × | × | × | × | × | × | × |
| 1-Butanol | × | × | × | × | × | × | × | × | × |
| Ethanol | × | × | × | × | × | × | × | × | × |
| Water | × | × | × | × | × | × | × | × | × |

| | Formula | Formula | Formula | Formula | Formula | Formula | Formula | Formula |
|---|---|---|---|---|---|---|---|---|
| | (10) | (11) | (12) | (13) | (14) | (15) | (16) | (17) |
| CF | ○ | ○ | ○ | ○ | ○ | ○ | ○ | ○ |
| CB | ○ | ○ | ○ | ○ | ○ | ○ | ○ | ○ |
| DCB | ○ | ○ | ○ | ○ | ○ | ○ | ○ | ○ |
| TCB | ○ | ○ | ○ | ○ | ○ | ○ | ○ | ○ |
| o-Xylene | ○ | ○ | ○ | ○ | ○ | ○ | ○ | ○ |
| Toluene | ○ | ○ | ○ | ○ | ○ | ○ | ○ | ○ |
| Tetralin | ○ | ○ | ○ | ○ | ○ | ○ | ○ | ○ |
| THF | Δ | Δ | ○ | ○ | ○ | ○ | ○ | ○ |
| DCM | Δ | Δ | ○ | ○ | ○ | ○ | ○ | ○ |
| Ethyl | × | × | Δ | Δ | Δ | Δ | Δ | Δ |
| Acetate | | | | | | | | |
| Acetone | × | × | Δ | Δ | Δ | Δ | Δ | × |
| n-Heptane | × | × | × | × | × | × | × | × |
| Methanol | × | × | × | × | × | × | × | × |
| 2-Propanol | × | × | × | × | × | × | × | × |
| 1-Butanol | × | × | × | × | × | × | × | × |
| Ethanol | × | × | × | × | × | × | × | × |
| Water | × | × | × | × | × | × | × | × |

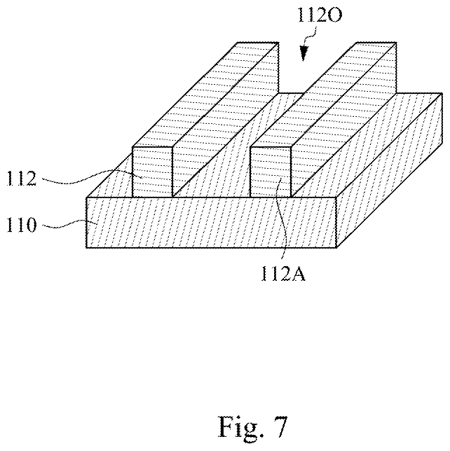

After operation S108 of FIG. 1, the portion 114A of the photoresist layer 114 is removed and the result is the patterned semiconductor layer 112 that has the opening 1120 as shown in FIG. 7. In the embodiments including the protection layer 113 and the release layer, the protection layer 113 and the release layer that are under the portion 114A of the photoresist layer 114 are removed together with the portion 114A of the photoresist layer 114. In some embodiments, after patterning the semiconductor layer 112, because the solubility of the semiconductor layer 112 in the second organic solvent is lower, the method of patterning semiconductor layer of the present disclosure further includes washing the patterned semiconductor layer 112 with the second organic solvent to remove the first organic solvent. This can avoid the semiconductor layer 112 being dissolved further by the first organic solvent residue because of its higher solubility. Moreover, the semiconductor layer 112 can have more obvious pattern boundary after washing with the second organic solvent. The method of patterning semiconductor layer of the present disclosure has many applications. For example, in an embodiment of the substrate 110 including an electrode, the opening 1120 as shown in FIG. 7 can be filled with a conductive material in the subsequent process to connect with the electrode in the substrate 110 and the electrode formed on the semiconductor layer 112. In this embodiment, the semiconductor layer 112 is used in an optical diode. In another embodiment, the opening 1120 shown in FIG. 7 is filled with an insulating material in the subsequent process to be a packaging layer.

Experiment 1 and Experiment 2 below describe specifically the features of the present disclosure. Although the following embodiments are provided, the material and its amount and ratio, the process details, and so on, can be modified appropriately without exceeding the scope of the present disclosure. Accordingly, the embodiments described below are not intended to limit the present disclosure.

In Experiment 1, the semiconductor layer 112 included the type I molecule having formula (1) and the type II molecule having formula (12) (i.e., P3HT and PCBM). The thickness of the semiconductor layer 112 was 150 nm. In the solution 120, the first organic solvent included o-xylene and the second organic solvent included n-heptane, in which the volume ratios of the first organic solvent to the second organic solvent were 10:1 (Embodiment 1), 5:1 (Embodiment 2), 2:1 (Comparative Embodiment 1), 1:1 (Comparative Embodiment 2), and 0:1 (Comparative Embodiment 3), respectively. In the operation of soaking the semiconductor layer 112 into the solution 120 to pattern the semiconductor layer 112, the soaking time in Embodiment 1, Embodiment 2, Embodiment 1, Comparative Embodiment 2, and Comparative Embodiment 3 was the same, for example, 60 seconds, and the temperature was also the same, for example, 20° C. The experimental results are shown in Table 2, where O indicates no overly dissolution or insufficient dissolution, while X Indicates overly dissolution or insufficient dissolution.

TABLE 2

| Embodiment | Embodiment | Comparative | Comparative | Comparative |
|---|---|---|---|---|
| 1 | 2 | Embodiment 1 | Embodiment 2 | Embodiment 3 |
| ◯ | ◯ | × | × | × |
| | | (insufficient dissolution) | (insufficient dissolution) | (insufficient dissolution) |

In Experiment 2, the semiconductor layer 112 included the type I molecule having formula (1) and the type II molecule having formula (12) (i.e., P3HT and PCBM). The thickness of the semiconductor layer 112 was 150 nm. In the solution 120, the first organic solvent included o-xylene and the second organic solvent included 2-propanol, in which the volume ratios of the first organic solvent to the second organic solvent were 10:1 (Embodiment 3), 5:1 (Embodiment 4), 2:1 (Comparative Embodiment 4), 1:1 (Comparative Embodiment 5), and 0:1 (Comparative Embodiment 6), respectively. In the operation of soaking the semiconductor layer 112 into solution 120 to pattern the semiconductor layer 112, the soaking time in Embodiment 3, Embodiment 4, Comparative Embodiment 4, Comparative Embodiment 5, and Comparative Embodiment 6 was the same, for example, 60 seconds, and the temperature was the same, for example, 20° C. The experimental results are shown in Table 3, where O indicates no overly dissolution or insufficient dissolution, while X indicates overly dissolution or insufficient dissolution. The difference between Experiment 2 and Experiment 1 is that the semiconductor layer 112 including formula (1) and formula (12) has a weaker solubility in 2-propanol compared with the solubility in n-heptane. Therefore, after the dissolution, Embodiment 3, Embodiment 4, Comparative Embodiment 4, Comparative Embodiment 5, and Comparative Embodiment 6 have more residues of the semiconductor layers 112 respectively compared with Embodiment 1, Embodiment 2, Comparative Embodiment 1, Comparative Embodiment 2, and Comparative Embodiment 3. In other words, the dissolution rate of the semiconductor layer 112 can be adjusted by different first organic solvents or second organic solvents.

TABLE 3

| Embodiment | Embodiment | Comparative | Comparative | Comparative |
|---|---|---|---|---|
| 3 | 4 | Embodiment 4 | Embodiment 5 | Embodiment 6 |
| ◯ | ◯ | × | × | × |
| | | (insufficient dissolution) | (insufficient dissolution) | (insufficient dissolution). |

The method of patterning semiconductor layer of the present disclosure used the first organic solvent and the second organic solvent that have different solubilities to the semiconductor layer to pattern the semiconductor layer. Compared with the conventional wet etching using the acid or alkaline solution, the method reduces the damage to the semiconductor layer and preserves the characteristics of the semiconductor layer. Compared with the conventional dry etching using vacuum equipment, the method simplifies the process and is easier to be implemented.

For one skilled in the art, the present disclosure may be modified and changed as long as not departing from the spirit and scope of the present disclosure. If the modifications and changes are within the scope and spirit of the claims that are appended, they are covered by the present disclosure.

What is claimed is:

1. A method of patterning semiconductor layer, comprising:
forming a semiconductor layer on a substrate;
forming a photoresist layer on the semiconductor layer;
patterning the photoresist layer to form an opening that exposes an exposed region of the semiconductor layer in the photoresist layer; and
dissolving the exposed region of the semiconductor layer with a solution to pattern the semiconductor layer, wherein the solution comprises a first organic solvent and a second organic solvent, a solubility of the semiconductor layer in the first organic solvent is greater than 1 mg/mL, and a solubility of the semiconductor layer in the second organic solvent is less than or equal to 1 mg/m L.

2. The method of claim 1, wherein the semiconductor layer comprises at least one type I molecule, at least one type II molecule, at least one type III molecule, or combinations thereof, wherein the at least one type I molecule has a structure of any one of following formula (1) to formula (11): 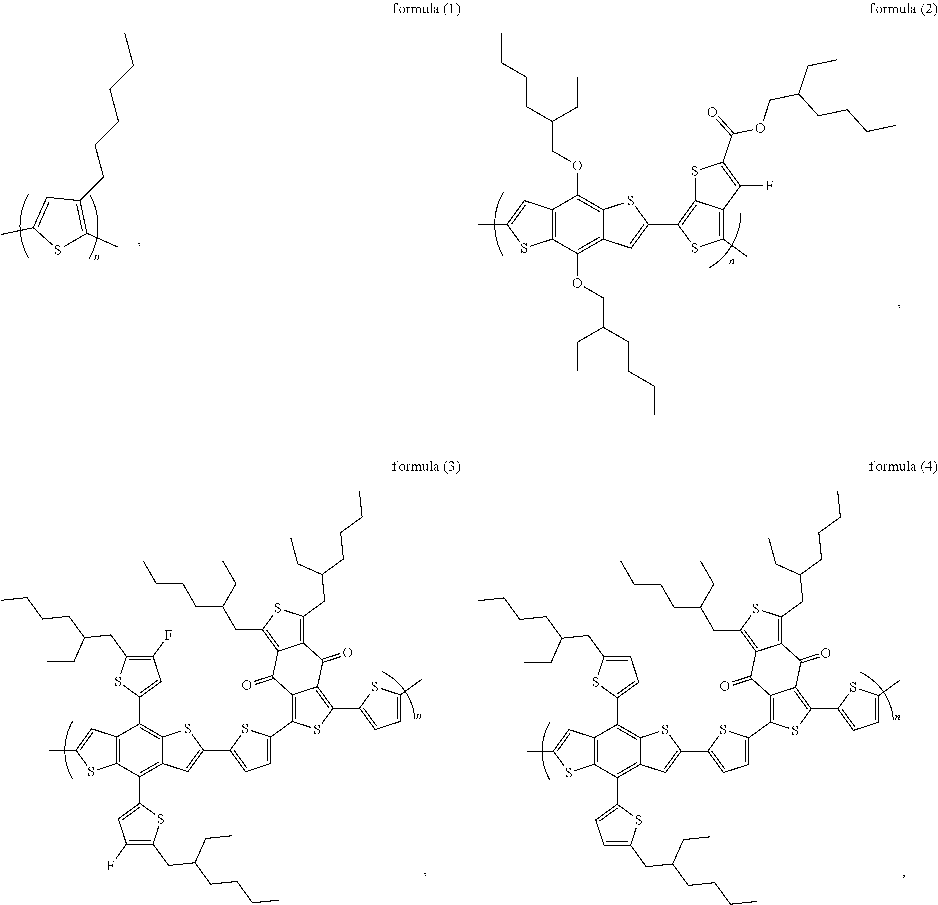 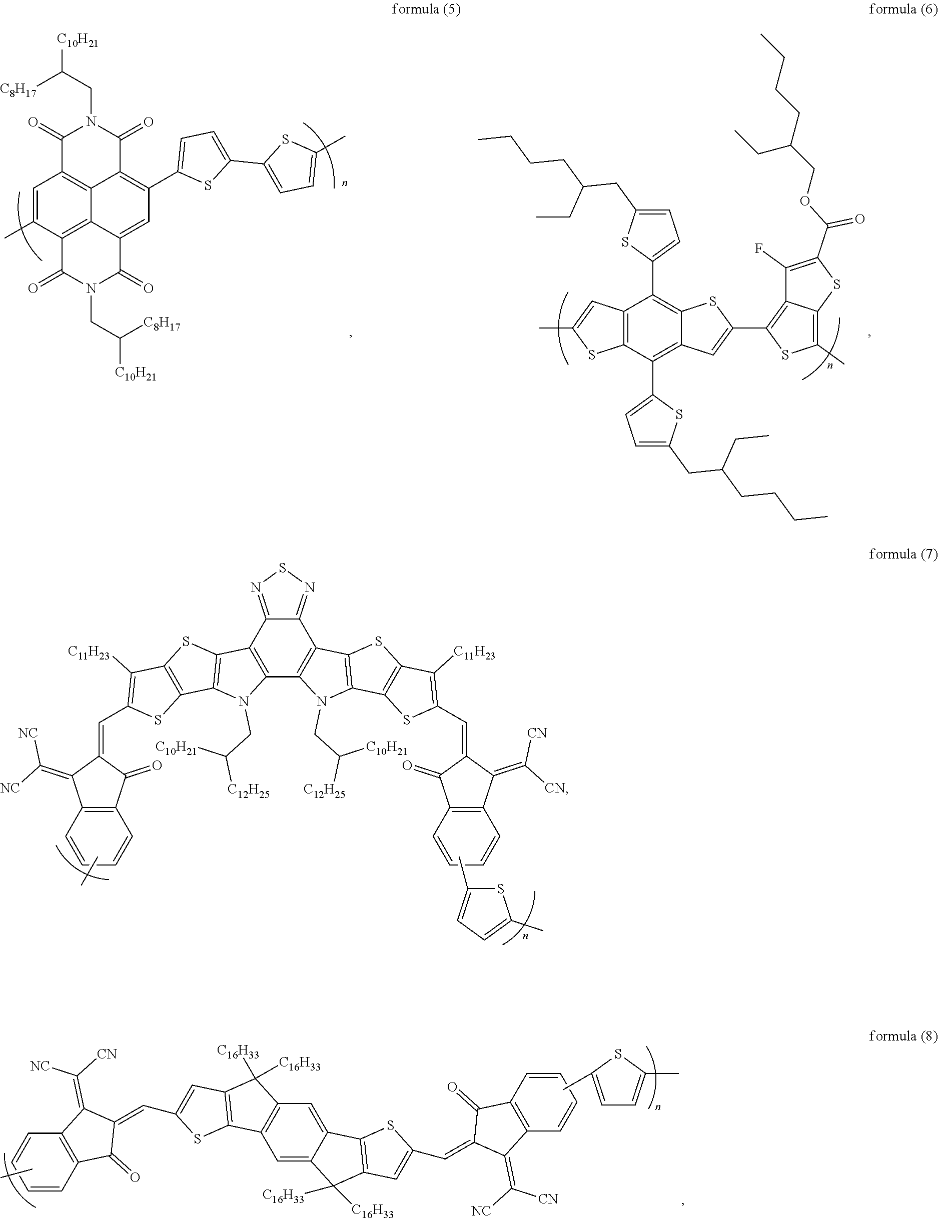 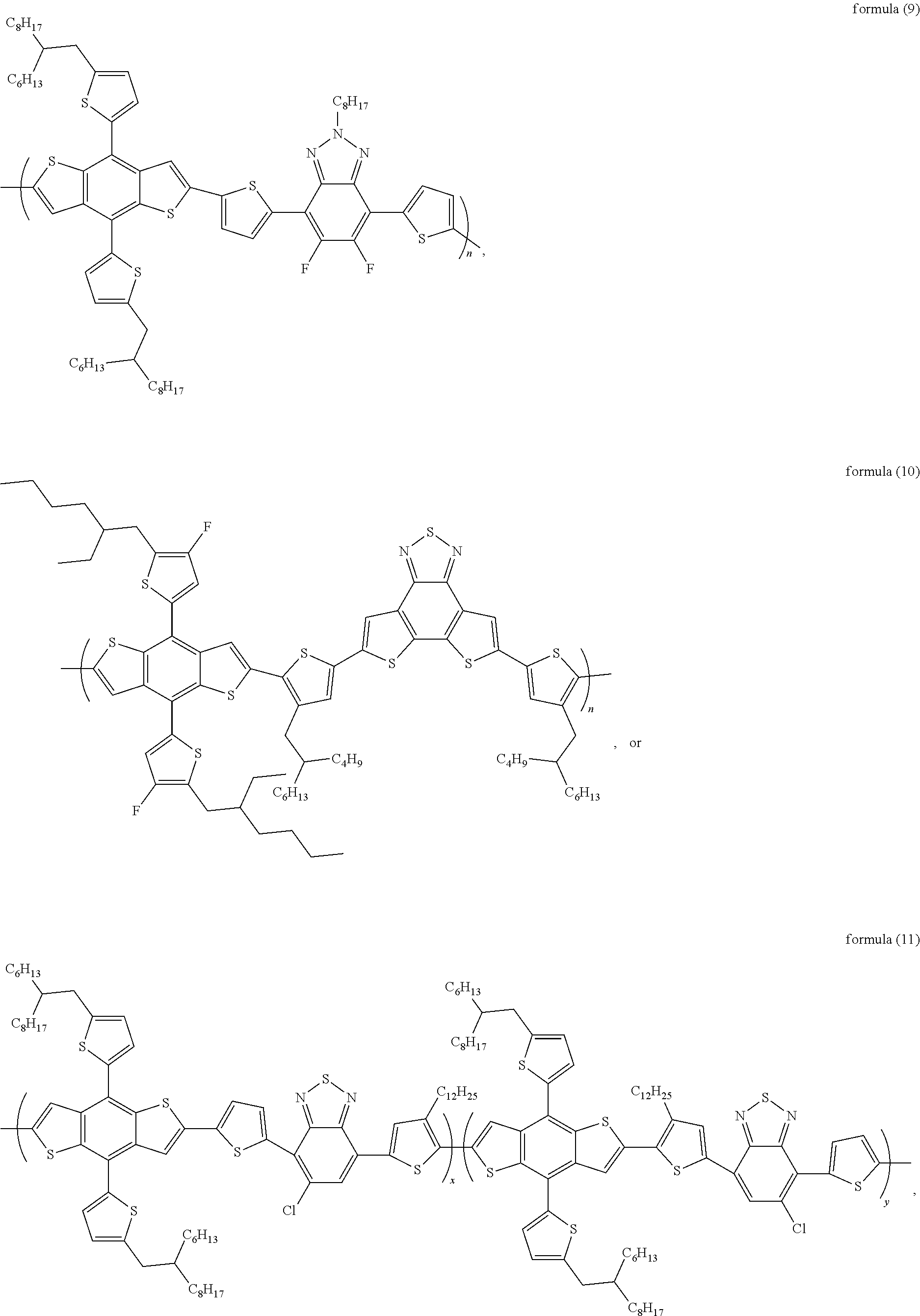
the at least one type II molecule has a structure of any one of following formula (12) to formula (16): 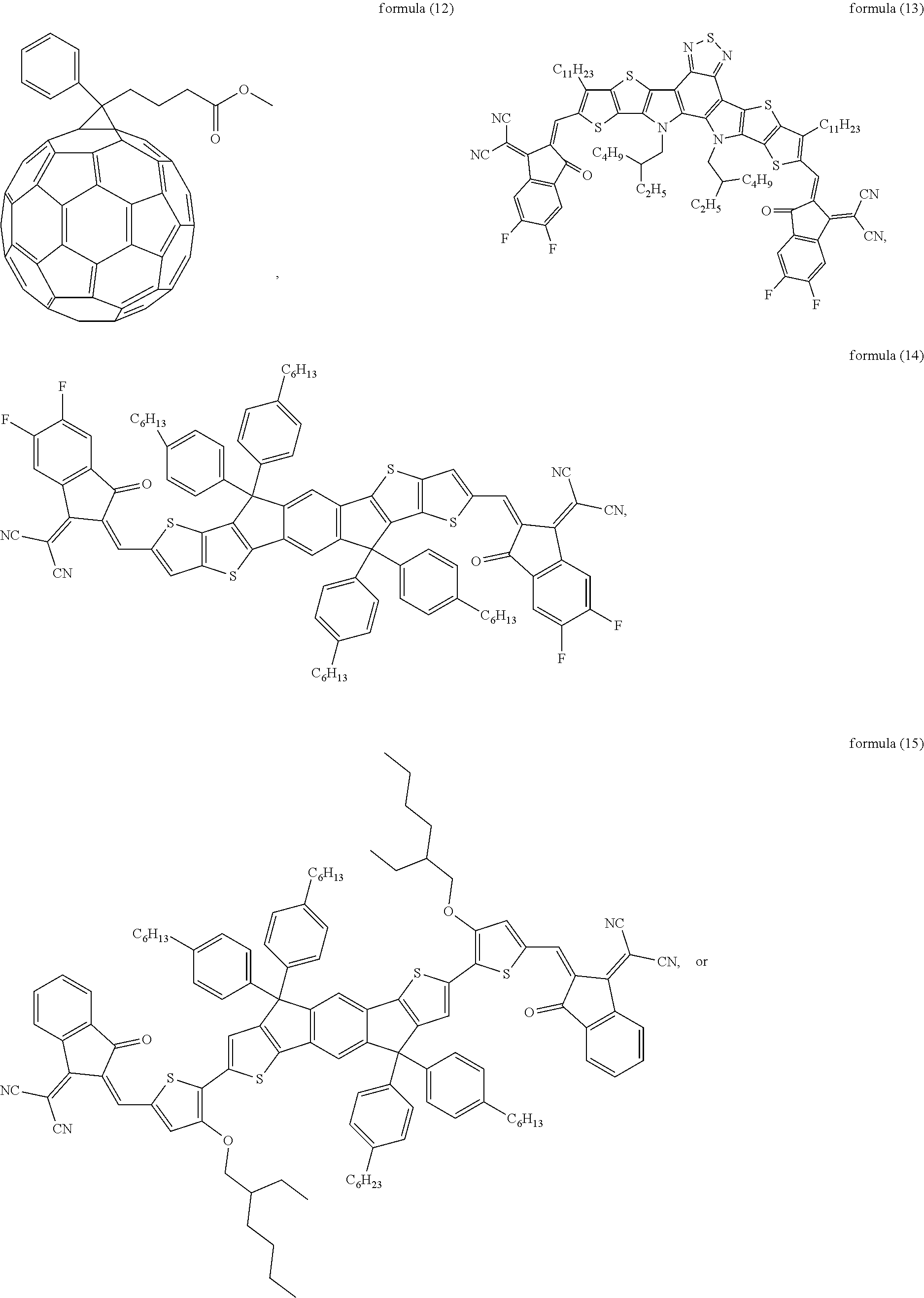 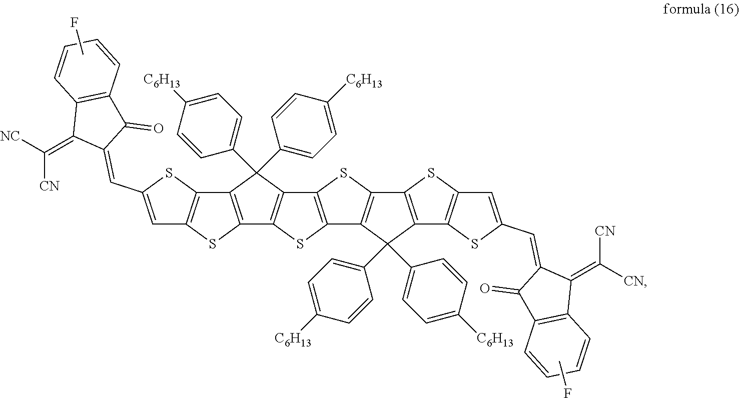
and the at least one type III molecule has a structure of following formula (17): 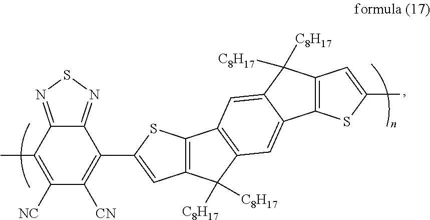
wherein n is between 1 and 500, x and y are mole fractions respectively, and a sum of x and y is 1.

3. The method of claim 2, wherein the first organic solvent comprises chloroform, chlorobenzene, o-dichlorobenzene, 1,2,4-trichlorobenzene, o-xylene, toluene, tetralin, tetrahydrofuran, dichloromethane, or combinations thereof.

4. The method of claim 3, wherein the second organic solvent comprises n-heptane, methanol, 2-propanol, 1-butanol, ethanol, water, or combinations thereof.

5. The method of claim 2, wherein when the semiconductor layer comprises the at least one type I molecule, the first organic solvent comprises chloroform, chlorobenzene, o-dichlorobenzene, 1,2,4-trichlorobenzene, o-xylene, toluene, tetralin, tetrahydrofuran, dichloromethane, or combinations thereof, and the second organic solvent comprises n-heptane, methanol, 2-propanol, 1-butanol, ethanol, water, ethyl acetate, acetone, or combinations thereof.

6. The method of claim 2, wherein when the semiconductor layer comprises the at least one type II molecule, the first organic solvent comprises chloroform, chlorobenzene, o-dichlorobenzene, 1,2,4-trichlorobenzene, o-xylene, toluene, tetralin, tetrahydrofuran, dichloromethane, ethyl acetate, acetone, or combinations thereof, and the second organic solvent comprises n-heptane, methanol, 2-propanol, 1-butanol, ethanol, water, or combinations thereof.

7. The method of claim 2, wherein when the semiconductor layer comprises the at least one type III molecule, the first organic solvent comprises chloroform, chlorobenzene, o-dichlorobenzene, 1,2,4-trichlorobenzene, o-xylene, toluene, tetralin, tetrahydrofuran, dichloromethane, ethyl acetate, or combinations thereof, and the second organic solvent comprises n-heptane, methanol, 2-propanol, 1-butanol, ethanol, water, acetone, or combinations thereof.

8. The method of claim 1, wherein a volume ratio of the first organic solvent to the second organic solvent is between 5:1 and 50:1.

9. The method of claim 1, further comprising after patterning the semiconductor layer, washing the semiconductor layer that is patterned with the second organic solvent to remove the first organic solvent.

10. The method of claim 1, further comprising before forming the photoresist layer, forming a protection layer on the semiconductor layer.

11. The method of claim 10, wherein the protection layer comprises the hydrophilic polymer or a low surface energy material.

12. The method of claim 10, further comprising before forming the protection layer, forming a release layer on the semiconductor layer.

13. The method of claim 12, wherein the release layer comprises a low surface energy material.

14. The method of claim 1, further comprising when dissolving the exposed region of the semiconductor layer, spraying the solution onto the semiconductor layer, spinning coating the solution onto the semiconductor layer, or soaking the semiconductor layer into the solution.

15. The method of claim 1, further comprising after dissolving the exposed region of the semiconductor layer, removing the patterned photoresist layer.
